(19) United States
(12) Patent Application Publication
(10) Pub. No.: US 2012/0092842 A1
(43) Pub. Date: Apr. 19, 2012

(54) ENCAPSULATED CIRCUIT DEVICE FOR SUBSTRATES HAVING AN ABSORPTION LAYER, AND METHOD FOR THE MANUFACTURE THEREOF

(76) Inventors: Jochen Neumeister, Stuttgart (DE); Reinhard Rieger, Brackenheim (DE)

(21) Appl. No.: 13/263,647

(22) PCT Filed: Feb. 26, 2010
(86) PCT No.: PCT/EP2010/052503

§ 371 Date: Dec. 23, 2011

(30) Foreign Application Priority Data
Apr. 21, 2009 (DE) 10 2009 002 519.

(51) Int. Cl. H05K 1/18; H05K 3/30

(52) U.S. Cl. 361/761; 29/841

(57) ABSTRACT

An encapsulated circuit device has a substrate, components configured on a substrate surface portion of a component side of the substrate, an encapsulation, at least one electrical contact having an outer portion projecting out of the encapsulation and an inner portion provided in the circuit device that is electrically connected to the substrate. The encapsulation includes a rigid outer encapsulation, which extends completely around the substrate, the components and the inner portion of the at least one electrical contact, as well as a compressible deformation absorption layer, which is provided between the components and the outer encapsulation and at least completely covers the substrate surface portion on which the components are configured.

### BACKGROUND OF THE INVENTION

1. Field of the Invention

The present invention relates to substrate-based circuits and, in particular, to circuits having a plurality of discrete or integrated components that are provided on the substrate.

2. Description of Related Art

In the case of substrate-based or printed circuit board-based circuits, a multiplicity of individual discrete or integrated components are affixed to a substrate, which, on the one hand, provides an electrical connection among the components and, on the other hand, provides a mechanical support. An insulation layer serves as a support for a circuit-board conductor layer whose structure defines the electrical connections of the electrical components. This circuit technology differs in principle from integrated circuits where a single silicon chip provides both a substrate, as well as all components, i.e., no components are mounted on the substrate.

Particularly in the case of power circuits, for example in the automotive sector, the circuit is provided for high-current applications, resulting in high loads in terms of power losses, current intensity and temperature. Moreover, numerous fields of application require that the circuit be largely protected from environmental influences. To attain greater mechanical stability and to permit dissipation of the temperature loads and the heat loss, ceramic substrates are used on which individual components are accommodated.

The published German Patent Application DE 102006033175 A1 describes an electronic module having a power section and a logic section which, together, are embedded in a shared module housing. Thus, the module housing is provided by the compound in which the circuits are embedded, the module housing rendering possible a protection from external influences and, at the same time, providing for connections as well as heat dissipation.

Since, on the one hand, a circuit module that has been potted as described above is protected and, on the other hand, is provided with a housing in a space-saving manner, the present invention likewise relates to an encapsulated structure. However, the described encapsulation by embedding or potting also entails disadvantages since materials having different properties, in particular different coefficients of thermal expansion, come into contact with one another. Stresses are produced at the boundary surface between the housing material and the component, respectively between the housing material and the substrate, in particular because the thermal expansion coefficient of the substrate differs from that of the surrounding housing material, but also because the components are made of many different materials; these mechanical stresses also being transferred by the mechanical connections provided by the housing to mechanical stresses among the components. This results in unreliable electrical contacts, interruptions, components that are influenced by mechanical stresses during operation thereof, and gap formations. Mechanical stresses of this kind arise, in particular, in applications that are performed over a broad temperature range or that entail a temperature range that differs significantly from the manufacturing temperature range.

However, in the automotive sector, in particular, circuits of this kind are used in the engine compartment, very significant temperature fluctuations usually occurring there. At the same time, the fields of application also relate to functions that are essential to the operation of a motor vehicle, so that, in the automotive sector, in particular, an especially high level of reliability must be provided in spite of the substantial temperature differences. Moreover, in high-power-output applications, the temperature differences that arise are not only temporal, but also spatial, particularly when working with high-power modules for electric drives in the vehicle sector, when controlling currents that relate to the electrical section of a hybrid drive, and also in the context of current generators or also electric generators for motor vehicles. It is immediately apparent from these fields of application that the circuit must be protected by a housing, whereby the circuit structure provided with the housing should be provided in an especially space-saving manner.

It is, therefore, an object of the present invention to provide a circuit device, as well as a method for the manufacture thereof, that is suited for the fields of application mentioned above and, in particular, for broad temperature ranges.

### BRIEF SUMMARY OF THE INVENTION

The present invention renders possible an especially space-saving circuit structure that is well protected from external influences and that also functions reliably even at very great temperature differences. In particular, by employing the circuit structure according to the present invention, mechanical stresses, which cause numerous problems, particularly in broad temperature application ranges, may be reduced by several orders of magnitude, the means for reducing the mechanical stresses involving only very little or no additional required space. The circuit is suited, in particular, for substrates and components having large dimensions, in particular for substrates which are substantially thicker than a silicon chip, without any appreciable mechanical stresses being produced, by the large enclosed volume in response to significant temperature variations. In addition, the present invention is suited for reducing mechanical stresses by several orders of magnitude, even when working with significant spatial temperature gradients within the circuit, as occur most notably in relatively large circuits due to heat accumulation. Thus, the present invention also makes it possible for a component, which generates considerable heat, to be mounted on the same substrate as a component, which has a significantly lower temperature, without any gaps or mechanical stresses being produced.

In the approach according to the present invention, a substrate, including the components mounted thereon, is provided with a rigid outer encapsulation in order to make possible a substantial mechanical stability and, at the same time, to mechanically separate the rigid outer encapsulation from the substrate and from the components through the use of an additional absorption layer. The purpose of the absorption layer is to absorb any stresses produced, in particular, in response to temperature variations induced by the relative movement among components of the circuit device having different thermal expansion coefficients. The absorption layer is provided as a compressible absorption layer, so that thermally induced movements of the substrate surface, respectively of the components, relative to the outer encapsulation are absorbed by the deformation of the absorption layer, without it exerting a significant pressure on parts of the circuit device that could adversely affect the operation of the circuit device. At the same time, the absorption layer is a place holder that prevents the rigid outer encapsulation, during placement thereof, from coming in direct contact with stress-sensitive parts of the circuit device. The deformation of the absorption layer may be an elastic deformation having a spring constant or having an elasticity modulus that is significantly below that of the rigid outer encapsulation. In addition, the deformation of the absorption layer may be plastic; in comparison to the rigid outer encapsulation, only minimal stresses resulting in a change in volume; or a combination of elastic and plastic deformation is possible. The absorption layer absorbs a substantial portion of the deformations that correspond to the change in volume, a substantial portion being described as at least 90% of the change in volume.

While the rigid outer encapsulation features a minimal mechanical flexibility that is measurable on the basis of the elasticity modulus, the compression modulus, the shear modulus, the Poisson number or a combination thereof, the absorption layer provides a significantly greater deformability, so that negligible mechanical stresses in the absorption layer are already enough to move significantly more relative volume than in the rigid outer encapsulation. It is provided, in particular, that the absorption layer be considerably more mechanically flexible than the substrate and than the components that are used. In a numerical comparison, the elasticity modulus of the compressible absorption layer is less than 10% of that of the rigid outer encapsulation, particularly in the case of soft absorption layers, less than 1/100, 1/500, 1/1000, or 1/10000 of that of the rigid outer encapsulation. While the rigid outer encapsulation has a rigidity of a hard plastic, respectively molding or injection-molding material that is normally used for encapsulating circuits, the absorption layer has a rigidity that is typical of silicon or a silicon gel. The elasticity modulus comparisons also hold for the compression modulus. The comparisons mentioned here with regard to the compressibility, respectively the elasticity between the absorption layer and the outer encapsulation likewise apply to a comparison of the compressibility, respectively the elasticity between the absorption layer and the components, respectively between the absorption layer and the substrate. Thus, an absorption layer is preferably used whose elasticity modulus is less than 10% of that of the substrate, preferably less than 1/100 of that of the substrate. (In some inventive embodiments, the elasticity modulus of the absorption layer may be less than 1/500, 1/1000, 1/5000 or 1/10000 of that of the substrate.) The same also holds for a comparison of the mechanical properties of the absorption layer to those of the components used. It is thus ensured that the absorption layer is substantially more compressible than all of the other elements of the circuit device, so that, in response to relative movements induced by temperature differences, essentially only the absorption layer absorbs the ensuing mechanical compression or expansion. In this context, this signifies essentially that the absorption layer absorbs at least 95% of the change in volume resulting from the movement of the outer encapsulation, respectively the inner surface thereof, relative to the substrate and relative to the components. (In some cases, the absorption layer may be designed to absorb at least 99%, or also in other cases at least 90% of the change in volume.)

Thus, when manufacturing the circuit device according to the present invention, at least portions of the substrate and the components are covered with the absorption layer prior to placement of the outer encapsulation, so that, when the outer encapsulation is subsequently applied, it is ensured that it is not in direct contact with the substrate or the components, rather that a minimum layer thickness of the absorption layer is always provided between the encapsulation and the substrate, respectively the component. The minimum layer thickness depends on the temperature range to be expected, the different thermal expansion coefficients and on the dimensions. However, the minimum thickness is at least 50 μm. In particular, an absorption layer is provided in the device, respectively is applied in the process, that has a minimum thickness of 200 μm, 500 μm, 1 mm, 1.5 mm, 2 mm, 2.5 mm or 3 mm. This may relate to the entire absorption layer or also to only portions thereof. In addition, the thickness of the entire absorption layer or only in some areas may be up to 3 mm. This upper limit ensures a still acceptable heat dissipation. To minimize the additional space requirements and to not unnecessarily degrade the heat dissipation capacity of the encapsulation, the absorption layer has a maximum thickness of 5 mm. In addition, the absorption layer may be provided with a maximum thickness of 4 mm or 3 mm. A thickness of approximately 3 mm, 2 mm or of 1 mm is preferred for the entire absorption layer or only for parts thereof. Especially preferred, however, is a thickness of between approximately 1 mm and 2 mm. This is measured between positions of the outer encapsulation and an opposite component, respectively an opposite substrate position.

In addition, the circuit device according to the present invention preferably includes an electrical contact or contacting, which extends through the outer encapsulation and, in some instances, also through parts of the absorption layer, and which includes an outer portion that projects out of the encapsulation. The outwardly projecting outer portion may be used for realizing external electrical connections. Thus, starting from the substrate, the at least one electrical contact (respectively, the at least one contacting) extends from the substrate through the entire encapsulation; the encapsulation, at least the rigid outer encapsulation, completely surrounding the circuit device (except for the outer portion of the contact). The electrical contact may include a contact strip of wire strips or sheet-metal strips that are electrically connected to the substrate directly or via a bonding connection. The rigid outer encapsulation provides a means for mechanically fixing the electrical contact in position.

The absorption layer preferably covers the entire substrate surface of the component side, the component side of the substrate being the side on which the components are mounted. In addition, the absorption layer may, in fact, cover all of the components and the substrate surface present there (also between the components), an outer edge of the substrate surface remaining on which the electrical contact or the contact strip is provided. Alternatively, the absorption layer may also extend over the connections between the electrical contact and the substrate. In addition, the absorption layer may extend over the entire bottom side of the substrate. However, if the circuit device includes a heat sink that is mounted on the bottom side, then this is excluded from the absorption layer (inter alia, for thermal reasons), it also being possible for the absorption layer to cover the lateral surfaces of the substrate. To provide additional electrical insulation, in particular in the case of strict insulation requirements and given less than completely insulating absorption layer characteristics, a flexible insulation layer may be provided between the substrate/the components and the absorption layer that electrically insulates the absorption layer therefrom.

In addition to a flat heat sink in the form of a plate that is mounted on the bottom side of the substrate directly at the substrate and that is excluded from the absorption layer, the circuit device may also include a cap that is configured on the component side of the substrate. The cap has a planar surface that points away from the substrate, so that the process of applying the material that forms the subsequent rigid outer encapsulation is simplified, particularly when working with hard plastic material or molding material that is viscous upon application. The application of the material that forms the rigid encapsulation (=molding material), i.e., the application of an outer encapsulation layer, is carried out by a flow process in which the molding material that forms the outer encapsulation is cast in the context of a molding process. In this connection, a flowable molding material in the form of a molding compound (for example, a thermosetting plastic) is applied, preferably under pressure. In addition, the cap protects the substrate and the components from adverse external effects, such as deformation, during application of the (cast) outer encapsulation layer using this molding process. In addition, the cap protects the bonding connections from deformation during application of the (cast) outer encapsulation layer. Thus, the bonding connections are preferably configured underneath the cap. The solidified molding layer directly adjoins a planar surface of the cap, thereby ensuring that thermal conductivity is retained, ruling out that the heat dissipation from the substrate from the components to the outside is disturbed by unwanted inclusions. The cap may serve as additional protection from external mechanical action, and as a cooling element capable of dissipating the heat that is generated. The cap is preferably shaped in such a way that it is able to wrap around the highest component (in the mounted form) without contacting the same, preferably with a safety clearance of approximately 1 mm or less. The cap may cover all of the components or only a portion thereof, in particular, only the power components, or a power group of the components, and it completely encloses the components in question together with the substrate surface of the component side. Thus, the cap provides a space that is designed to fully accommodate the components located therein. In accordance with the present invention, the cap not only extends around the components in question, but also around the absorption layer that is formed on the substrate portion and on the components provided in the heat sink cap. Starting from the component or the substrate, the absorption layer extends at least partially or completely to the cap in order to thereby produce a continuous physical contact. This then serves the purpose of heat dissipation, in particular. In addition, a hollow space in the form of a slot may be provided between the cap and the absorption layer, respectively between the absorption layer and the component. Preferably, however, no slot is provided between the absorption layer and the cap. This is accomplished by providing the cap with one or a plurality of openings, so that the material of the absorption layer is able to be filled in completely to ensure that no slot is formed. The openings are used for pressure and volume compensation when filling in the absorption layer material, so that no air bubbles remain. Rather, during the filling-in process, all of the gas contained in the cap is removed, and the absorption layer material completely occupies the space. However, pressure or volume may also be compensated via targeted air bubbles in the absorption material or also via a residual quantity of air in the cap. The residual quantity of air, respectively the air bubbles is/are preferably located to a lesser degree or not at all above power components or other heat-generating components, but rather above components that generate only little or no heat, i.e., at a thermally uncritical site, in order not to prevent the heat dissipation through the air.

Both the cap, as well as the heat sink, which is mounted on the bottom side, are preferably made of metal, in particular having a sheet thickness of greater than 0.1 mm and, in particular, greater than 0.3 mm, to render possible a suitable heat dissipation and a mechanical protection from externally applied mechanical stresses. The sheet thickness is preferably less than 1 mm or less than 0.5 mm. In accordance with one specific embodiment of the present invention, the cap is completely surrounded by the outer encapsulation, it also being alternatively possible that an outer portion of the cap is excluded from the outer encapsulation. Thus, in the case of a heat-generating component, the heat may be dissipated via the absorption layer directly to the heat sink cap to the outside or via the substrate and via the heat sink directly to the outside.

The material of the absorption layer preferably has a high thermal conductivity, as is typical of silicon, for example, in order to avoid the formation of a heat island underneath the absorption layer. It is preferably provided that the absorption layer be made of silicon material, of rubber, of silicon gel or of another electrically insulating gel. Generally, the absorption layer includes insulating material to ensure that there is no unwanted electrical contact for the substrate, nor for the components configured thereon. The absorption layer on the component side (top side) of the substrate may be made of a different material than the opposite absorption layer (bottom side). For example, if a heat sink or a cooling plate is configured on the bottom side, then the material of the absorption layer on the bottom side is, most notably, thermally conductive and, in some instances, less electrically insulating than the material on the bottom side, while the material of the absorption layer on the top side has especially electrically insulating properties and, in comparison, is less thermally conductive. On the bottom side of the substrate that includes a heat sink, for example, the absorption layer may also be constituted of thermally conductive adhesive which is used to attach the heat sink to the substrate.

Therefore, the manufacturing method according to the present invention provides for populating a substrate surface portion of a component side with discrete and integrated components, mounting the electrical contact on the substrate, as well as the subsequent encapsulation according to the present invention of the thereby resulting circuit. The enclosing process initially includes application of the absorption layer, whereupon the cap is placed, if indicated. Following the application of the absorption layer at the above described sites and, in some instances, following the mounting of the cap, the rigid outer encapsulation is installed at the above described locations. An outer portion of the electrical contacts is excluded from the entire encapsulation. In some instances, a corresponding outer portion of the cap or of the heat sink is also excluded. To implement the method, the materials and components of the above described circuit device are used. The application of the absorption layer includes, for example, immersing the substrate into an absorption layer material. Alternatively to the immersion, the absorption layer material may also be spray-deposited or extrusion-coated on, or also pressed or stamped on (in particular on the bottom side, i.e., the side facing away from the components). In particular, the absorption layer is applied by immersing the populated substrate into a solidifying liquid, for example into a liquid silicon, it being possible for the immersion to be provided completely or incompletely, depending on the desired extent of the absorption layer. In the case of applied liquid silicon, this is cross-linked in the usual curing steps, respectively solidification duration.

Instead of silicon, a soft plastic may, in principle, also be used that is applied, for example, by injection molding. Another specific embodiment provides for using synthetic resin as absorption layer material that is solidified in accordance with customary technologies (UV curing or heating). Another specific embodiment includes a soft plastic material, synthetic resin or, in particular, a mixture thereof. Thus, the process of forming the absorption layer includes solidification of the absorption layer following application, if necessary; in the case of gel materials, in particular, no complete hardening taking place by virtue of the mechanical properties of gel. Rather, the desired mechanical properties of the absorption layer are provided following solidification thereof. The outer encapsulation may likewise be applied to the absorption layer in a soft state, for example by extrusion, the outer encapsulation hardening, for example, by cooling, by cross-linking or in a different manner. During extrusion, the material is liquefied by heating of the same in advance. Therefore, the material is in a hot (liquefied) state during extrusion. Hard plastic materials or a mixture of initially flowable and curable hard plastic materials and solid particles are suited as material for the outer encapsulation, i.e., for the molding compound.

The absorption layer used for the circuit device, respectively the absorption layer provided by the method is thus preferably a deformable layer, whereas the outer encapsulation forms a hard, in principle elastic and not very flexible outer layer. Thus, the outer encapsulation is a hard material which absorbs externally acting mechanical loads and which, by virtue of its mechanical stability, protects the interior of the component from external mechanical effects. At the same time, the outer encapsulation is mechanically stable, not brittle, and elastically absorbs forces, even at an elasticity modulus that is typically high for hard materials, for example greater than 10 kN/mm². Both layers preferably feature a high thermal conductivity. It is an aim of the manufacturing method that the morphology of both layers correspond to a non-porous structure. The layers are constituted of continuous solid material that may have individual bubbles that are inherent to the manufacturing, an efficient transfer of heat and a stable mechanical structure being ensured. The absorption layer may have a constant layer thickness or may be provided with a minimum thickness as described above. In particular, the thickness of the absorption layer between the power components and the outer encapsulation preferably corresponds to a minimum of all thicknesses of the layer, to render possible an efficient transfer of heat. At the same time, the thickness provided there preferably corresponds at least to the minimum thickness.

Ceramic substrates, in particular, are suited as a substrate, or also circuit boards, respectively printed circuit boards having one or a plurality of conductor track planes. The substrate may be made of a composite material, for example of a ceramic composite material, or also of paper or hard paper substrates or glass mat, respectively fiberglass substrates, which are impregnated, respectively saturated with a resin material or plastic, for example phenol (in particular as a combination with hard paper) or epoxy (in particular, di-/tetra-epoxy), polyimide or Teflon. Composite materials having ceramic or ceramic materials are suited as a substrate. The substrate has at least one metal layer, preferably of copper or silver, that is used for electrically connecting the components. In addition, the substrate may include a heat-conducting plate, preferably of copper, on the side opposite the component, this metal plate serving as a heat sink. Suited as a ceramic substrate are LTCC ceramics, HTCC ceramics, for example having printed circuits, or also ceramic substrates, hybrid ceramic substrates or standard ceramic substrates, for example having aluminum oxide, that are produced using thick-film or thin-film technology. The substrate may be sintered or be in the form of a continuous layer. In addition, it may support printed circuits, as well as one or a plurality of patterned conductor-track layers.

The components preferably include high-current components that may be passive or active. Active components include diodes, transistors, thyristors, triads or integrated circuits, and the passive components include resistors, coils and capacitors. Some or all of the components may be designed as high-power components, in particular the active components, as well as the coils or resistors that are connected as a shunt resistor. Components designed as power components include at least one heat-emitting surface that faces toward or away from the substrate, as well as, optionally, a heat sink that is directly mounted on the component for dissipating the heat into the absorption layer. Besides power-intensive components, components designed for lower power may also be used, for example passive components or integrated circuits for data processing tasks, signal processing tasks or logic modules. Generally, the components may be unpackaged components or components which may have a separate housing including contacts, in particular ICs or less complex active/passive components, for example power semiconductors or prefabricated passive components, such as inductors, resistors or capacitors having a housing (for example as potted components).

All substrates, which are in the form of ceramic substrates here, may also be designed as a fiber composite substrate, such as hard paper circuit boards or epoxy circuit boards or other fiber/plastic composite boards.

The circuit device according to the present invention may have a multiplicity of contacts for through-hole or SMD mounting. The contacts are preferably configured in at least one row, for example in pairs of mutually opposing rows, it being possible for the circuit device to have, in particular, one or two pairs of these contact strips. The total number of the contacts may be 2 to 80 or more, depending on the application and function. The circuit device may be significantly larger than a typical IC housing, for example having edge lengths of >10 mm, >35 mm, or >55 mm; for example, it may have a size of 35 mm×55 mm.

### BRIEF DESCRIPTION OF THE DRAWINGS

FIG. 1 shows a first specific embodiment of the circuit device according to the present invention.

FIG. 2 shows a second specific embodiment of the circuit device according to the present invention.

FIG. 3 shows a third specific embodiment of the circuit device according to the present invention.

FIG. 4 shows a fourth specific embodiment of the circuit device according to the present invention.

FIG. 5 shows a fifth specific embodiment of the circuit device according to the present invention.

### DETAILED DESCRIPTION OF THE INVENTION

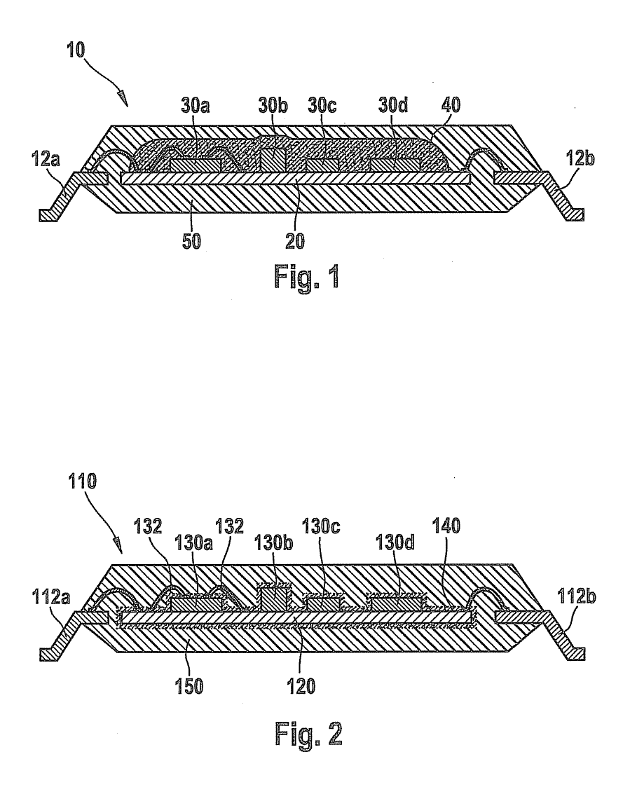

FIG. 1 shows a circuit device 10 according to the present invention that includes electrical contacts 12a,b. Circuit device 10 encompasses a substrate 20 on which components 30a-d are provided. SMD soldering techniques or an electrically conductive adhesive are/is used to mount components 30a-d on the component side of substrate 20 which bears a patterned conductor layer. All components 30a-d are surrounded by a compressible absorption layer 40, which completely covers the components, as well as a portion of the component side of the substrate surface. On the one side, the absorption layer covers a connection to the electrical contact 12a (i.e., a bonding connection to the substrate), whereas the connection to contact 12b provided on the substrate is not covered by the absorption layer. The absorption layer does not cover the complete component side of substrate 20. Rather an edge remains between the covered substrate surface portion and the complete component side on which electrical contact 12b (not, however, electrical contact 12a) is connected to the substrate. An outer encapsulation 50 covers the entire circuit, as well as the entire compressible absorption layer, inner portions of electrical contacts 12a and b being provided within outer encapsulation 50 to render possible a connection to the substrate (a bonding connection in FIG. 1), whereas the electrical contacts also include outer portions that project out of the outer encapsulation and thus out of the entire encapsulation. Electrical contacts 12a and b are in the form of pins or sheet-metal strips, which may be further connected to external circuits, for example by a soldered connection.

FIG. 2 shows a second specific embodiment of circuit device 110 according to the present invention that encompasses a substrate 120 that is populated with components 130a-d. The components are connected via soldered connections and also via bonding connections 132 to the substrate, respectively to a conductor layer of the substrate. Electrical contacts 112a,b provide the external contact to the encapsulated, populated substrate 120. In the same way as the first specific embodiment shown in FIG. 1, circuit device 110 of FIG. 2 includes an outer encapsulation 150, as well as an absorption layer whose location 140 is symbolically illustrated by a dotted line. It is discernible in FIG. 2 that absorption layer 140 extends completely around the populated substrate (i.e., also all the components). In contrast to the specific embodiment in FIG. 1 where the outer encapsulation directly contacts the bottom side of the substrate, the lateral surfaces of the substrate, as well as the outer edge of the substrate on the component side, there is always a minimum distance, which corresponds to the thickness of the absorption layer, between the outer encapsulation and substrate, respectively components. Since the absorption layer in FIG. 2 reaches around the entire substrate, the substrate also includes connections to electrical contacts 112a,b, the connections being provided as bonding points on the substrate. In this case, a connection, which connects the substrate to the electrical contacts (a bonding connection), completely penetrates the absorption layer. In some instances, other electrical contacts of the device that are present are not shown in FIG. 2. The line illustrated by dots merely shows the location of the absorption layer, however, not its extent. As in FIG. 1, the absorption layer has a minimum thickness which defines a minimum distance between the component surface, respectively substrate surface and the outer encapsulation. This distance corresponds to the above described thickness of the absorption layer that is formed in accordance with a minimum thickness.

As does the first specific embodiment illustrated in FIG. 1, the specific embodiment illustrated in FIG. 2 does not feature any heat sink or cap, so that the heat generated by the Components penetrates through absorption layer 40, 140, as well as through outer encapsulation 50, 150 to the outside. Some of the heat is transmitted via the substrate to a bottom section of the outer encapsulation shown in FIGS. 1 and 2 that, in turn, dissipates the heat to the outside.

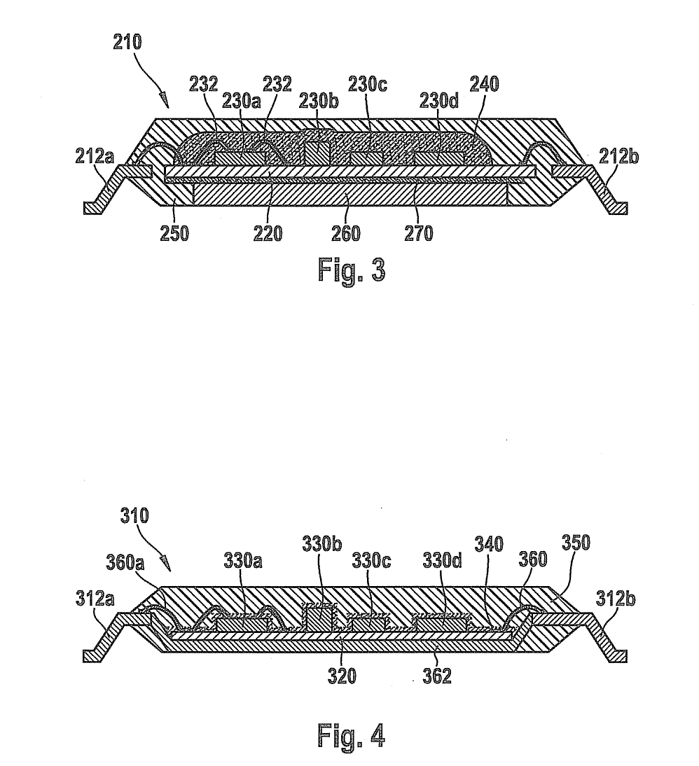

FIG. 3 shows a third specific embodiment of circuit device 210 according to the present invention that includes a heat sink 260 in the form of a metal plate (for example, of steel, copper or aluminum). As in the case of the specific embodiments of FIGS. 1 and 2, the third specific embodiment shown in FIG. 3 includes a substrate 220 that is populated with components 230a-d. The components are connected to the substrate using a soldering technique, as well as via bonding connections 232. As in the case of the first specific embodiment shown in FIG. 1, circuit device 210 shown in FIG. 3 includes an absorption layer 240 that merely covers a portion of the component side of the substrate surface (and not the entire substrate). An edge remains where an electrical contact 212b is connected to the substrate, a further contact 212a being connected to the substrate via a point of contact that is covered by the absorption layer. The connection of the electrical contacts to the substrate that are provided on the substrate, may be completely covered by the absorption layer, may not be covered by the absorption layer, or may be covered by the absorption layer with a thickness that is smaller than the minimum thickness of the absorption layer.

In comparison to FIGS. 1 and 2, circuit device 210 illustrated in FIG. 3 includes a heat sink 260 that is connected by an adhesive 270 to the bottom side of the substrate, the bottom side opposing the component side of the substrate. The outer encapsulation extends completely around absorption layer 240, as well as around components 230a-d provided therein, as well as around the inner portion of electrical contacts 212a, however, is only directly contiguous to heat sink 260, without further covering the same; one outer side of the heat sink that faces away from the substrate not being covered by the outer encapsulation. This renders possible a direct heat dissipation of the heat generated by components 230 a-d through substrate 220, through adhesive 270 to heat sink 260, whose exterior dissipates the heat to the outside. On the bottom side of the circuit device, outer encapsulation 250 is in alignment with the outer surface of heat sink 260. In this case, it is discernible that heat sink 260 does not cover the entire bottom side of substrate 220, rather only the surface opposing the components on the component side. In preferred specific embodiments, a cooling element 260 is provided on the bottom side of the circuit device only where power components are provided on the opposite side of the substrate that generate considerable heat that must be dissipated.

While the illustrated specific embodiment has a cooling element that is smaller than the substrate, for example in order to fulfill external manufacturing specifications, it is preferred that the substrate (i.e., the bottom side thereof) be completely covered with the cooling element (not shown). The cooling element is preferably as large as or larger than the substrate in order to render possible an optimal heat dissipation. In this preferred specific embodiment, which is not shown, the cooling element extends completely around the bottom side of the substrate.

FIG. 4 shows a fourth specific embodiment of circuit device 310 according to the present invention having a substrate 320 on which components 330a-d are mounted. The specific embodiment shown in FIG. 4 corresponds in numerous details to that of FIG. 2. An important distinction is that, in FIG. 4, a stamped grid (that provides the electrical contacts after they have been separated from a stamped frame of the stamped grid part) forms a heat sink on the bottom side of the circuit device. Thus, the contacts and the heat sink may be provided by a stamped grid part to be stamped. Circuit device 310 illustrated in FIG. 4 also encompasses an absorption layer whose location 340 is illustrated by a dotted line. Absorption layer 340 is applied to the entire component side of the substrate and covers the substrate surface, as well as components 330a-d provided there. In addition, portions of the lateral edges of the substrate are covered, this configuration being optional. The bottom side of the substrate opposing the component side is directly connected to a heat sink of stamped grid 362. The heat sink forms a common stamped grid with contacts 312 prior to the stamping, the stamping separating these components from one another. Contacts, which are connected to the stamped grid, are formed throughout as a metal sheet together with the stamped grid. The different hatching of the contacts illustrated in FIG. 4 (and the other figures) compared to the stamped grid does not connote the mechanical dissimilarity of these components, rather merely represents the different functions. During manufacturing, the populated or unpopulated substrate is fastened to the heat sink of stamped grid 362 before outer encapsulation 350 is mounted. In principle, the substrate may be joined as a populated or as a still unpopulated substrate to a heat sink provided on the bottom side of the substrate. Heat sinks may be fastened to the substrate using thermally conductive adhesive, for example.

In accordance with one preferred specific embodiment, contacts 312a and 312b, as well as stamped grid 362 remaining after the stamping are originally formed in one piece in the form of a stamped part. All further electrical contacts are not shown in the cross-sectional representation of FIG. 4.

In a specific embodiment (not shown) that is similar to the specific embodiment of FIG. 4, contacts in the circuit device are not connected to the stamped grid remaining following the stamping, in order to provide individual connections that may have a different potential; from an electrical standpoint, connections provided by a stamped frame are irrelevant following removal of the stamped frame. Prior to the end of production, a contact that is not connected (similar to contact 312a) is a portion of the one stamped part (i.e., formed in one piece therewith). However, it is not connected directly, rather via a stamped frame, to the stamped grid remaining following the stamping (for example, stamped grid 362). The stamped frame is removed by the stamping process that is carried out following application of the layer (layers); and the indirect connection between the contact and the remaining stamped grid is released. The applied layers and encapsulations ensure the mechanical (and not electrically conductive) connection between the contact and the remaining stamped grid. All contacts and the stamped grid remaining following the stamping preferably form a stamped part that encompasses a frame on which all contacts are configured, the frame being removed by the stamping process and only those contacts directly connected with the stamped grid following the stamping remaining which, prior to the stamping, were also directly connected thereto and not only via the frame.

The heat sink of the stamped grid is not covered on the bottom side by outer encapsulation 350. The side walls of the heat sink of stamped grid are curved toward the substrate and covered by outer encapsulation 350. The heat sink composed of the stamped grid is mechanically connected to electrical contact 312b, so that outer encapsulation 350 is preferably produced following connection of electrical contacts 312a,b to heat sink 362 made of the stamped grid. The connection between electrical contact 312a and 312b and heat sink 362 constituted of the stamped grid may be provided in any given form. The connection is preferably a galvanic, electrical connection that remains following the stamping of a stamped grid part. The components remaining after the stamping form both heat sink 362, as well as electrical contact 312b. Thus, the heat sink and electrical contact 312b are formed in one piece.

The additional electrical connection 360 or 360a between electrical contact 312a,b and the substrate (i.e., the two outer bonds directly at contact 312a,b) is optional. The connection between the substrate and heat sink 362 is provided by a bonded connection, as is the bonded connection between the heat sink in FIG. 3 and the substrate. Bonded connections of this kind provide a further mechanical relieving, as is also made possible by the absorption layer.

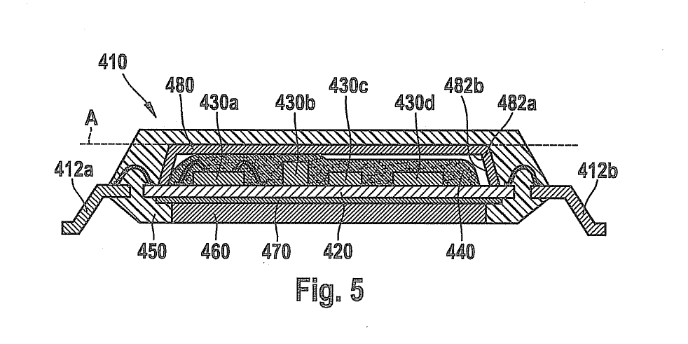

FIG. 5 shows a fifth specific embodiment of circuit device 410 according to the present invention that includes both a bottom heat sink 460, which is connected via an adhesive 470 to the bottom side of substrate 420, and also a cap 480. Bottom heat sink 460 and cap 480 are configured on both sides of substrate 420, the cap being configured on the component side of substrate 420. On the component side, the substrate bears components 430a-d, which are completely surrounded by absorption layer 440. In addition, surface portions of substrate 420 provided there are covered by absorption layer 440. The ends of cap 480 which are oriented toward substrate 420 are directly connected to the component side of substrate 420. Provided outside of these contact points between cap 430 and substrate 420 on the component side of the substrate is an edge where the substrate is connected to electrical contacts 412a,b. As in the other specific embodiments, a bonding connection is used for this purpose whose contact point is configured outside of the substrate surface portion on which the components are located and which is situated outside of the cap. The absorption layer is provided completely within cap 480 and is in direct contact with a portion of an inner surface of the cap, as well as with all remaining surfaces of components 430a-d. In addition, a portion, respectively portions 482a,b of the inner side of cap 480 is/are separated by a gap, for example an air gap, from absorption layer 440. This gap is preferably removed in that the absorption material is completely filled into the cap. To this end, the cap preferably has openings to allow air to escape, making it possible for the absorption material to fill in the cap completely (and without gaps). If caps without openings are used (in some instances, making it possible to save costs), then a gap is formed as described, which (depending on the use) does not pose any significant disadvantages to the circuit function. It is discernible from FIG. 5 that a high-power component 430a, in particular, is in a direct heat-transmitting contact via the absorption layer with cap 480 which, in turn, directly adjoins the outer encapsulation, thereby allowing the heat to be dissipated to the outside. In the specific embodiment shown in FIG. 5, the cap is completely covered by outer encapsulation 450, particularly on the outer side of cap 480 that faces away from the substrate. This results, in fact, in a mechanical protection of the cap by the encapsulation provided there, but has inherent limitations in terms of the heat transfer. If a gap is configured, for example, above substrate portions having low-power components or not having any components, then this does not entail any disadvantages for the circuit function. As in the specific embodiment illustrated in FIG. 4, as well, bottom heat sink 460 may also be part of a stamped grid that also provides contacts 412a,b. The heat sink and contacts (mutually joined by a single stamped grid) may also be separated by the stamping.

In another specific embodiment (not shown), the outer encapsulation extends, starting from the substrate, only to the outer side of the cap that faces away from the substrate. In FIG. 5, a dashed line indicates this plane A, up to which the outer encapsulation extends and in which the outer side of the cap extends that faces away from the substrate. Thus, this outer side of the cap is not covered by the outer encapsulation. Rather, it abuts directly on the surroundings of the circuit device in order to thereby make possible a direct heat exchange. However, the side walls of this cap are covered with the outer encapsulation in order to thereby provide a stable mechanical connection of the cap in the circuit device, in particular to the substrate and the electrical contacts. The thus described specific embodiment encompasses two heat sink elements, i.e., a bottom heat sink plate and a cap whose outer sides are not covered by the encapsulation. The heat sinks are preferably made of metal or include metal for a more efficient heat transfer. Copper, aluminum or also steel may be used as metal, for example. The heat sink elements are preferably initially mounted, i.e., by adhesion or using a different type of fastening, to then be covered by the outer encapsulation in that the heat sinks and portions of the substrate are extrusion-coated with the compound of the outer encapsulation.

In accordance with the manufacturing method according to the present invention, the cooling element (in the form of a stamped grid) is a support for the substrate. The cooling element is imprinted with electrically insulating thermally conductive adhesive; the thermally conductive adhesive may also be applied in a different manner. The cooling element, which functions as a heat sink, underneath the substrate is larger than the surface over which the thermally conductive adhesive is applied. The cooling element, which functions as a bottom heat sink, is a component of the stamped grid. The substrate (for example, an LTCC substrate) is placed in the thermally conductive adhesive. Prior to the placement, the substrate is already populated with components, bonds (inner bonding) and heat sink cap. The substrate is also bonded by the thermally conductive adhesive. The surface, over which the thermally conductive adhesive is applied, is larger than the substrate. The substrate is completely configured in the thermally conductive adhesive surface. The heat sink cap is smaller than the substrate (to be able to accommodate outer bonds). Subsequently thereto, gel is filled into the cap through a bore in the cap. An insulated conductive track routing is possible in several locations in the substrate. The outer bonds are applied subsequently thereto. Finally, molding compound (epoxide) is used to form a rigid outer encapsulation in the course of a casting process (remolding) in order to preferably completely cover the circuit device. This manufacturing method is suited for all circuit devices according to the present invention having a cooling element on the bottom side of the substrate, in particular for the specific embodiments of FIGS. 3-5.

In one alternative manufacturing method according to the present invention, the cooling element is not a component of the stamped grid. In this case, the cooling element is provided as a plate, for example, onto which the (populated) substrate is fastened. Apart from that, the same steps are used in this alternative manufacturing method according to the present invention as in the manufacturing method described in the previous paragraph. The alternative manufacturing method is suited for all circuit devices according to the present invention having a cooling element on the bottom side of the substrate, in particular for the specific embodiments of FIGS. 3-5.

1-10. (canceled)

11. An encapsulated circuit device, comprising:
a substrate;
a plurality of components configured on a substrate surface portion of a component side of the substrate;
an encapsulation; and
at least one electrical contact having an outer portion projecting out of the encapsulation and an inner portion which is inside the encapsulation and is electrically connected to the substrate;
wherein the encapsulation includes a rigid outer encapsulation and a compressible absorption layer, the rigid outer encapsulation completely surrounding the substrate, the components; and the inner portion of the at least one electrical contact, and wherein the compressible absorption layer is provided between the components and the outer encapsulation, the compressible absorption layer covering at least a Portion of the substrate surface portion on which the components are configured, and wherein the compressible absorption layer is configured to absorb at least a portion of a deformation resulting from thermally-induced movement of the Substrate surface and the components relative to the outer encapsulation.

12. The circuit device as recited in claim 11, wherein the compressible absorption layer covers the entire substrate surface portion of the component side of the substrate.

13. The circuit device as recited in claim 11, wherein the compressible absorption layer has: i) at every location, a thickness in the range between 50 μm and 3 mm; and ii) an elasticity modulus less than 1/10 of the elasticity modulus of the rigid outer encapsulation.

14. The circuit device as recited in claim 12, wherein the compressible absorption layer includes at least one of a silicon material, an electrically insulating gel, a soft plastic material, and a synthetic resin.

15. The circuit device as recited in claim 11, further comprising:
a cap;
wherein the compressible absorption layer is provided only on the component side of the substrate, and wherein the cap and the component side of the substrate enclose at least a portion of the compressible absorption layer, and wherein the cap has an inner surface at least partially in direct physical contact with a surface of the compressible absorption layer opposing the substrate.

16. A method for manufacturing an encapsulated circuit device having a substrate, a plurality of components, at least one electrical contact, and an encapsulation, the method comprising:
providing the components on a substrate surface portion of a component side of the substrate;
affixing an inner portion of the at least one electrical contact to the substrate for electrically connecting the contact to the substrate; and
enclosing the substrate with the encapsulation, the encapsulation including a compressible absorption layer and a rigid outer encapsulation layer, wherein the enclosing includes:
applying the compressible absorption layer to the components and to at least one substrate surface portion on which the components are provided, such that the components and the at least one substrate surface portion are completely covered by the absorption layer; and
applying the rigid outer encapsulation layer to the entire applied absorption layer and to the entire substrate such that the inner portion of the at least one electrical contact is completely surrounded by the encapsulation and an outer portion of the at least one electrical contact projects out of the encapsulation;
wherein the absorption layer includes a compressible material such that the absorption layer is configured to absorb at least a portion of deformation resulting from a thermally-induced movement of the substrate surface and the components relative to the outer encapsulation layer.

17. The method as recited in claim 16, wherein the compressible absorption layer covers the entire substrate surface portion of the component side of the substrate.

18. The method as recited in claim 16, wherein the compressible absorption layer has: i) at every location, a thickness in the range between 50 μM and 3 mm; and ii) an elasticity modulus less than 1/10 of the elasticity modulus of the rigid outer encapsulation.

19. The method as recited in claim 18, wherein the application of the absorption layer includes:
one of i) immersion into a liquid or flowable absorption layer material, ii) spray deposition of the liquid or flowable absorption layer material, or iii) extrusion-coating or stamping-on the liquid or flowable absorption layer material; and
curing the absorption layer material to form the absorption layer by one of cooling, cross-linking, UV curing, or heat curing.

20. The method as recited in claim 16, further comprising:
providing a cap on the absorption layer prior to the application of the rigid outer encapsulation layer;
wherein the absorption layer is provided only on the component side of the substrate, and wherein the cap and the component side of the substrate enclose the entire absorption layer, and wherein the cap has an inner surface at least partially in direct physical contact with a surface of the absorption layer opposing the substrate.
